(19) United States
(12) Patent Application Publication
(10) Pub. No.: US 2026/0365768 A1
(43) Pub. Date: Nov. 19, 2026

(54) SOLUBLE POLYFUNCTIONAL VINYL AROMATIC COPOLYMER, PRODUCTION METHOD THEREOF, CURABLE RESIN COMPOSITION AND CURED PRODUCT OF SAME

(71) Applicant: NIPPON STEEL CHEMICAL & MATERIAL CO., LTD., Tokyo (JP)

(72) Inventor: Shinichi Iwashita, Tokyo (JP)

(73) Assignee: NIPPON STEEL CHEMICAL & MATERIAL CO., LTD., Tokyo (JP)

(21) Appl. No.: 19/140,071

(22) PCT Filed: Nov. 16, 2023
(86) PCT No.: PCT/JP2023/041350

§ 371 Date: Jun. 17, 2025

(30) Foreign Application Priority Data
Dec. 23, 2022 (JP) 2022-206258

(51) Int. Cl. C08F 212/08; C08F 2/06; C08F 6/12; C08F 257/02; C08J 3/14; C08J 5/18; C08L 25/08; C09D 125/08; C09D 151/00

(52) U.S. Cl. CPC C08F 212/08; C08F 2/06; C08F 6/12; C08F 257/02; C08J 3/14; C08J 5/18; C08L 25/08; C09D 125/08; C09D 151/003; C08J 2325/08; C08J 2453/02; C08J 2471/12; C08L 2203/206; C08L 2205/03

(57) ABSTRACT

Provided is a soluble polyfunctional vinyl aromatic copolymer that can yield a resin cured product or a formed product with improved dielectric properties, heat resistance, adhesion reliability in an elevated-temperature manufacturing process, resin flowability, and a coefficient of linear thermal expansion. Disclosed is a soluble polyfunctional vinyl aromatic copolymer, which is a polyfunctional vinyl aromatic copolymer including a structural unit derived from a divinyl aromatic compound (a) and a structural unit derived from a monovinyl aromatic compound (b), in which the copolymer contains structural units of both a vinyl group and a 1,2-substituted ethylene group as unsaturated functional groups, the number of functional groups of the unsaturated functional group is within a specific range, and a functional group equivalent of the number of functional groups of the 1,2-substituted ethylene group is a predetermined value or more, a method for producing the copolymer, and a resin composition thereof.

### TECHNICAL FIELD

The present invention relates to a novel soluble polyfunctional vinyl aromatic copolymer excellent in heat resistance, solubility, formability, and long-term adhesion reliability, a method for producing the same, and a curable composition containing the copolymer. The present invention also relates to a film formed from the curable composition, a cured product obtained by curing the same, a curable composite material comprising the curable composition and a base material, a laminate comprising the cured product and metal foil, and copper foil with a resin.

### BACKGROUND ART

With an increase in an amount of information communication in recent years, information communication in high frequency bands has been increasingly performed, and in order to reduce transmission loss in high frequency bands, electrical insulating materials with superior electrical properties, in particular a low dielectric constant and a low dielectric loss tangent have been demanded. Furthermore, since printed circuit boards or electronic components using such electrical insulating materials are exposed to high-temperature solder reflow upon mounting, materials with high heat resistance, i.e., a high glass transition temperature, have been desired. In particular, recently, lead-free solder with a high melting point has been used due to environmental concerns, so that there has been an increasing demand for electrical insulating materials with higher heat resistance. In response to these demands, a curable resin using vinyl-based compounds having various chemical structures has been proposed.

As such vinyl-based compounds, Patent Literature 1 discloses a soluble polyfunctional vinyl aromatic copolymer obtained by having polymerized a divinyl aromatic compound and a monovinyl aromatic compound in an organic solvent in the presence of a Lewis acid catalyst and an initiator of a specific structure such as 1-chloroethylbenzene, 1-bromoethylbenzene, or bis(1-chloro-1-methylethyl)benzene at a temperature of 20 to 100 °C. Also, Patent Literature 2 discloses a method for producing a soluble polyfunctional vinyl aromatic copolymer having a molecular weight distribution controlled by cationic polymerization of a monomer component containing 20 to 100 mol % of a divinyl aromatic compound at a temperature of 20 to 120 °C in the presence of a quaternary ammonium salt, using a Lewis acid catalyst and an initiator of a specific structure.

The soluble polyfunctional vinyl aromatic copolymer obtained by the techniques disclosed in these two patent literatures has excellent solubility to a solvent, and a cured product obtained by using this copolymer exhibits physical properties such as a high glass transition temperature and excellent heat resistance. The soluble polyfunctional vinyl aromatic copolymer polymerized by the methods disclosed in Patent Literatures 1 and 2; however, contains in a product, a large amount of highly polar impurities due to a catalyst such as chlorine, and therefore is not satisfactory in terms of dielectric properties. Also, there is a concern that a defect such as circuit peeling caused by a chlorine impurity may occur in a humid and hot environment.

Patent Literature 3 describes, in addition to a divinyl aromatic compound and a monovinyl aromatic compound, a copolymer obtained by a polymerization method in which an oxo acid catalyst that selectively produces a vinylene group is compounded with a Lewis base compound. When the vinyl-based compound obtained by this method is exposed to an elevated process temperature; however, adhesive strength between a circuit layer and a resin layer decreases, resulting in that problems such as circuit peeling may have occurred.

Patent Literature 4 discloses a soluble polyfunctional vinyl aromatic copolymer containing a divinyl aromatic compound, styrene, and a monovinyl aromatic compound other than styrene, and includes a specific terminal group structure within a certain range. Although the soluble polyfunctional vinyl aromatic copolymer obtained by this method exhibits excellent physical properties such as heat resistance, compatibility, dielectric properties, and reliability in a humid and hot environment, no investigations have been made on resin flowability, a coefficient of linear thermal expansion in the vicinity of an environmental temperature upon use thereof, or adhesiveness after exposure to an elevated temperature and high humidity environment.

### CITATION LIST

### Patent Literature

Patent Literature 1: JP4338951B
Patent Literature 2: JP4717358B
Patent Literature 3: JP6833723B
Patent Literature 4: JP7126493B

### SUMMARY OF INVENTION

As described above, conventional vinyl-based compounds are insufficient in terms of dielectric properties, heat resistance, adhesion reliability in an elevated-temperature manufacturing process, resin flowability, and a coefficient of linear thermal expansion, as insulating materials for high-end circuit boards.

The present invention has been made in consideration of the above-described problems, and an object of the present invention is to provide a soluble polyfunctional vinyl aromatic copolymer excellent in all of dielectric properties, heat resistance, adhesion reliability in an elevated-temperature manufacturing process, resin flowability, and a coefficient of linear thermal expansion, a method for producing the same, and a curable composition containing the copolymer. The present invention also relates to a film formed from the curable composition, a cured product obtained by curing the same, a curable composite material comprising the curable composition and a base material, a laminate comprising the cured product and metal foil, and copper foil with a resin.

As a countermeasure against the above-described problems, the present inventors have found that a polyfunctional vinyl aromatic copolymer having a specific structure is a suitable material.

Namely, the present invention is directed to a soluble polyfunctional vinyl aromatic copolymer, which is a polyfunctional vinyl aromatic copolymer comprising a structural unit derived from a divinyl aromatic compound (a) and a structural unit derived from a monovinyl aromatic compound (b), wherein the structural unit derived from a divinyl aromatic compound (a) has a vinyl group-containing unit represented by the following formula (a1), a 1,2-substituted ethylene group-containing unit represented by the following formula (ta2), a cross-linked structural unit represented by the following formula (a2), and a structural unit represented by the following formula (ta1) containing both a vinyl group and a 1,2-substituted ethylene group, and the structural unit derived from a monovinyl aromatic compound (b) has a structural unit represented by the following formula (b1) and a 1,2-substituted ethylene group-containing terminal unit represented by the following formula (tb1), wherein the polyfunctional vinyl aromatic copolymer has a total number of unsaturated bond functional groups (excluding an unsaturated bond group in an aromatic ring) in one molecule of 2.1 or more and less than 3.5, a functional group equivalent of 1,2-substituted ethylene groups derived from the following formulae (ta1), (ta2), and (tb1) of 1,000 g/eq. or more, a number-average molecular weight of 300 to 10,000, and a molecular weight distribution (Mw/Mn) represented by a ratio of a weight-average molecular weight to a number-average molecular weight of 50 or less, is soluble in toluene, xylene, tetrahydrofuran, dichloroethane, or chloroform, and does not comprise a halogen element other than fluorine as an impurity in an amount of 1 ppm or more:

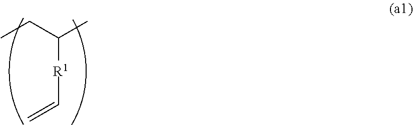

wherein R1 represents an aromatic hydrocarbon group having 6 to 30 carbon atoms;

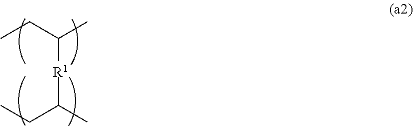

wherein R1 is as defined for formula (a1);

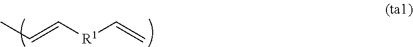

wherein R1 is as defined for formula (a1);

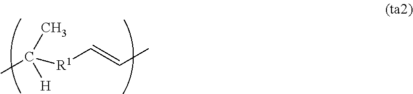

wherein R1 is as defined for formula (a1);

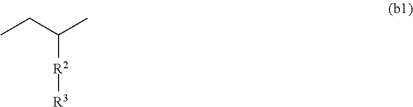

wherein R2 represents an aromatic hydrocarbon group having 6 to 30 carbon atoms, and R3 represents hydrogen or a hydrocarbon group having 1 to 12 carbon atoms; and

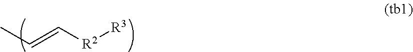

wherein R2 and R3 are as defined for formula (b1).

Using the soluble polyfunctional vinyl aromatic copolymer obtained by the present invention enables obtaining a resin cured product or a formed product with improved dielectric properties, heat resistance, adhesion reliability in an elevated-temperature manufacturing process, resin flowability, and a coefficient of linear thermal expansion. The present invention also enables providing a film formed from this novel curable resin composition, a cured product obtained by curing the same, as well as a curable composite material comprising the above-described curable resin composition and a base material, a cured product thereof, a laminate comprising the cured product and metal foil, and copper foil with a resin.

### BRIEF DESCRIPTION OF DRAWING

FIG. 1 shows a 1H-NMR chart of the copolymer obtained in Example 1.

### DESCRIPTION OF EMBODIMENTS

Next, the soluble polyfunctional vinyl aromatic copolymer of the present invention will be described in detail. The soluble polyfunctional vinyl aromatic copolymer of the present invention is composed of a structural unit derived from a divinyl aromatic compound (a) and a structural unit derived from a monovinyl aromatic compound (b), in which the structural unit derived from a divinyl aromatic compound (a) has a vinyl group-containing unit represented by the following formula (a1), a 1,2-substituted ethylene group-containing unit represented by the following formula (ta2), and a cross-linked structural unit represented by the following formula (a2), and a structural unit represented by the following formula (ta1) containing both a vinyl group and a 1,2-substituted ethylene group, and the structural unit derived from a monovinyl aromatic compound (b) has a structural unit represented by the following formula (b1) and a 1,2-substituted ethylene group-containing terminal unit represented by the following formula (tb1).

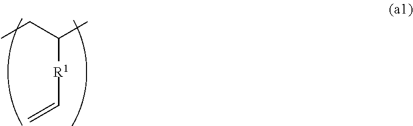

wherein R1 represents an aromatic hydrocarbon group having 6 to 30 carbon atoms.

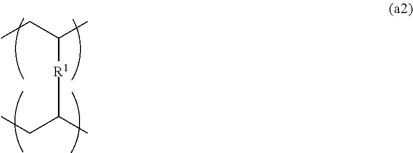

wherein R1 is as defined for formula (a1).

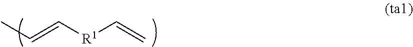

wherein R1 is as defined for formula (a1).

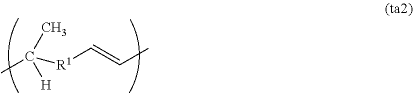

wherein R1 is as defined for formula (a1).

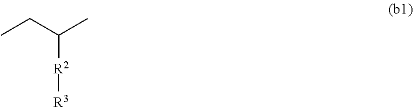

wherein R2 represents an aromatic hydrocarbon group having 6 to 30 carbon atoms, and R3 represents hydrogen or a hydrocarbon group having 1 to 12 carbon atoms.

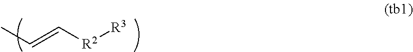

wherein R2 and R3 are as defined for formula (b1).

The soluble polyfunctional vinyl aromatic copolymer of the present invention is characterized in the total number of unsaturated bond functional groups in one molecule of 2.1 or more and less than 4.0. Herein, the total number of unsaturated bond functional groups does not include an unsaturated bond group constituting an aromatic ring. The unsaturated bond functional group contains vinyl groups contained in the above formulae (a1) and (ta1) and the 1,2-substituted ethylene groups derived from (ta1), (ta2) and (tb1).

The number of unsaturated bond functional groups can be calculated from the following (Expression 1). Herein, the number-average molecular weight is a value measured by GPC, and the vinyl equivalent is a value calculated by iodine value measurement by the Wijs method.

Number of unsaturated bond functional groups=number-average molecular weight/vinyl equivalent [Expression 1]

The number of unsaturated bond functional groups less than 2.1 in one molecule renders the insufficient number of cross-linking points upon curing of the copolymer in a processing step, resulting in a large coefficient of linear thermal expansion. The number of unsaturated bond functional groups exceeding 4.0, on the other hand, allows an unsaturated bond to remain after curing of the copolymer in a processing step, as a result of which the copolymer is deteriorated due to a thermal history of the processing step, thereby adversely affecting its physical properties.

The number of unsaturated bond functional groups in one molecule is preferably 2.2 or more and 3.8 or less, and more preferably 2.4 or more and 3.6 or less.

Among the unsaturated bond functional groups, the 1,2-substituted ethylene groups particularly derived from (ta1), (ta2) and (tb1) have low reactivity and are therefore likely to remain even after curing treatment in a processing step. The remaining 1,2-substituted ethylene group causes a deterioration. The proportion of this 1,2-substituted ethylene group present can be represented as the functional group equivalent of a 1,2-substituted ethylene group, and the functional group equivalent of the 1,2-substituted ethylene group can be calculated from the number of unsaturated bond functional groups calculated from the above (Expression 1), the proportion of the 1,2-substituted ethylene group present in unsaturated bonds calculated from 1H NMR, and the number-average molecular weight described above, using the following (Expression 2).

Functional group equivalent of 1,2-substituted ethylene group=number-average molecular weight/(number of unsaturated bond functional groups×proportion of 1,2-substituted ethylene group present) [Expression 2]

In order not to arise the problems described above, the functional group equivalent of the 1,2-substituted ethylene group is 1,000 g/eq. or more. It is preferably 2,000 or more and more preferably 2,500 or more.

In each of formulae (a1), (a2), (ta1) and (ta2), R1 denotes an aromatic hydrocarbon group having 6 to 30 carbon atoms, which is derived from the divinyl aromatic compound (a), and therefore can be understood from the explanation thereof. Specifically, R1 is preferably an aromatic hydrocarbon group having 6 to 12 carbon atoms and more preferably a phenylene group, a biphenylene group or a naphthylene group. In formulae (b1) and (tb1), R2 represents an aromatic hydrocarbon group having 6 to 30 carbon atoms, and R3 represents hydrogen or a hydrocarbon group having 1 to 12 carbon atoms. Specifically, R2 is preferably an aromatic hydrocarbon group having 6 to 12 carbon atoms and more preferably a phenylene group, a biphenylene group or a naphthylene group. R3 is preferably hydrogen or a saturated hydrocarbon group having 1 to 12 carbon atoms, more preferably hydrogen or a saturated hydrocarbon group having 1 to 6 carbon atoms, and still more preferably hydrogen or a saturated hydrocarbon group having 1 to 3 carbon atoms.

Mn (herein, Mn is a number-average molecular weight in terms of standard polystyrene measured by gel permeation chromatography) of the soluble polyfunctional vinyl aromatic copolymer of the present invention, is 300 to 10,000. When Mn is less than 300, the amount of monofunctional copolymer contained in the copolymer increases, so that heat resistance of a cured product decreases, whereas Mn exceeding 10,000 facilitates generation of gel and increases viscosity and melt viscosity, causing decrease in forming processability. Mn is preferably 500 to 5,000, more preferably 700 to 2,500, and still more preferably 900 to 2,000.

A molecular weight distribution (Mw/Mn) is in the range of 50.0 or less. Mw/Mn exceeding 50.0 arises problems such as deterioration of the processing characteristics of the copolymer and generation of gel. Mw/Mn is preferably 30.0 or less, more preferably 20.0 or less, still more preferably in the range of 1.1 to 15.0, and most preferably in the range of 5.0 to 12.0.

The soluble polyfunctional vinyl aromatic copolymer preferably has a vinyl equivalent of 150 to 1,000 g/eq., more preferably 200 to 800 g/eq., and still more preferably 300 to 500 g/eq.

The soluble polyfunctional vinyl aromatic copolymer of the present invention is soluble in a solvent selected from toluene, xylene, tetrahydrofuran, dichloroethane, or chloroform. Herein, being soluble in a solvent means that 5 g or more and preferably 10 g or more of the copolymer is dissolved in 100 g of a solvent at 25 °C. In order to be a polyfunctional copolymer that is soluble in a solvent, the copolymer is required to allow a vinyl group of divinylbenzene to partially remain uncross-linked and to have an appropriate degree of crosslinking.

The soluble polyfunctional vinyl aromatic copolymer of the present invention is characterized in that a compound after production does not contain a halogen element other than fluorine as an impurity in an amount of 10 ppm or more thereof. Depending on the catalyst type used in a polymerization step or the like, a halogen element may be mixed into the copolymer. The copolymer containing a halogen element may cause deterioration of dielectric properties as well as migration, or the like, which may adversely affect electrical reliability.

The soluble polyfunctional vinyl aromatic copolymer, when formed into a resin composition containing a radical polymerization initiator, has a minimum melt viscosity (η1) of preferably 100 Pa·s or less, more preferably 70 or less, and still more preferably 40 or less. The ratio of the melt viscosity (η2) at a temperature 5 °C higher than the temperature at which η1 is achieved, to η1, (η2/η1), is less than 5.0 and preferably less than 4.5. When η1 is more than 100 Pa·s, the resin does not soften sufficiently, resulting in having poor resin flowability, and a poor circuit filling property when used as a multilayer board, BUF, or the like. The resin flowability can be evaluated by the method described in “JIS C 6521”, and from the viewpoint of a circuit filling property, it is preferably 15% or more and more preferably 20% or more. The ratio of η2 to η1 (η2/η1) of 5.0 or more allows a softened resin to be cured before filling a circuit due to an extremely fast rate of curing of resin, resulting in a resin having a poor circuit filling property also in this case.

The soluble polyfunctional vinyl aromatic copolymer of the present invention can be preferably produced by using a divinyl aromatic compound (a) and a monovinyl aromatic compound (b) in a ratio such that (a) is 18 mol % or more and less than 35% relative to the total of (a) and (b), adding a Lewis acid catalyst (d) free of a halogen other than fluorine and a Lewis base compound (e), and performing polymerization at a temperature of 85 to 120 °C.

In the case of using less than 18 mol % of the divinyl aromatic compound (a), the proportion of the unsaturated bond functional groups of (a1) and (ta1) structures in the copolymer decreases, which leads to lowered cross-linking density, resulting in deterioration in CTE. In the case of (a) contained in an amount of 35 mol % or more, on the other hand, the proportion of the (a1) and (ta1) structures in the copolymer becomes excessive, and an unsaturated bond remains after curing of the copolymer, resulting in deteriorated physical properties due to a thermal history in a processing step. The divinyl aromatic compound (a) is preferably used in a ratio such that (a) is 25 mol % or more and less than 33% relative to the total of (a) and (b).

As the divinyl aromatic compound (a), for example, diisopropenylbenzene, divinylbenzene, diisopropenylnaphthalene, divinylnaphthalene, diisopropenylbiphenyl, and divinylbiphenyl are preferably used, but are not limited thereto. These compounds each include an isomer such as an m-isomer or a p-isomer, and may be a mixture of these isomers.

Examples of the monovinyl aromatic compound (b) include vinyl aromatic compounds such as styrene, vinylnaphthalene, vinylbiphenyl, and α-methylstyrene; nuclear alkyl-substituted vinyl aromatic compounds such as methylstyrene, dimethylstyrene, and ethylvinylbenzene; and cyclic vinyl aromatic compounds such as indene, acenaphthylene, benzothiophene, and coumarone, but are not limited thereto. These compounds also include each isomer, and may be mixtures of isomers.

As a copolymerization monomer component of the raw material, in addition to the divinyl aromatic compound (a) and the monovinyl aromatic compound (b), other monomers such as a trivinyl aromatic compound, a trivinyl aliphatic compound, a divinyl aliphatic compound, and a monovinyl aliphatic compound may be used within a range that does not impair the effects of the present invention. When compounded, it may be preferably compounded in an amount of, for example, less than 30 mol % relative to the total of all monomer components.

The copolymer of the present invention can be obtained by polymerization at a temperature of 85 to 120 °C. When polymerization is performed at a temperature exceeding 120 °C, selectivity of the reaction is significantly deteriorated, and a reaction frequency between the copolymers increases with (a1) and (ta1) in the copolymer as reaction points, resulting in an increase in molecular weight distribution and gelation. Polymerization performed at a temperature below 85 °C improves selectivity of the reaction and inhibits the above-described reaction between the copolymers. On the other hand, a chain transfer reaction of the monomers (a) and (b) that occurs in the course of propagation reaction is also sufficiently inhibited, so that the number of chains in the copolymer is likely to increase, making it difficult to keep a number-average molecular weight low. In polymerization at a temperature below 85 °C, it might be possible to keep the molecular weight of the copolymer low by decreasing the proportion of (a1) and (ta1) which are reaction points in the copolymer can be decreased; however, this method causes a decrease in cross-linking density as described above, resulting in deterioration in CTE.

The Lewis acid catalyst (d) used in polymerization of the copolymer of the present invention is a compound composed of a metal ion (acid) and a ligand (base), and can be used without any particular limitations as long as it is free of a halogen compound other than a fluorine atom in a molecule and can accept an electron pair. Among them, from the viewpoint of the thermal decomposition resistance of a soluble polyfunctional vinyl aromatic copolymer to be obtained, a metal fluoride or a complex thereof is preferred, and in particular, divalent to hexavalent metal fluorides or complexes thereof such as B, Al, Ga, In, Si, Ge, Sn, Pb, Sb, Bi, Ti, W, Zn, Fe and V are preferred. These catalysts can be used singly or in combination of two or more thereof. When a catalyst containing a halogen other than a fluorine atom is used, a halogen ion liberated from the catalyst is added to the copolymer, causing a deterioration of physical properties. From the viewpoint of control of the molecular weight and molecular weight distribution of a soluble polyfunctional vinyl aromatic copolymer to be obtained and its polymerization activity, an ether complex of boron trifluoride is most preferably used. Herein, examples of ether of the ether complex include diethyl ether and dimethyl ether.

The Lewis acid catalyst (d) is preferably used within the range of 0.001 to 50 mol and more preferably 0.01 to 20 mol, relative to 100 mol of the total of all monomer components. It is most preferably 0.05 to 10 mol. The amount exceeding 50 mol leads to a too high polymerization rate, making it difficult to control a molecular weight distribution. The amount less than 0.001 mol leads to a too low polymerization rate, resulting in increased costs and an unsuitable catalyst for industrial implementation.

In the method for producing a soluble polyfunctional vinyl aromatic copolymer of the present invention, one or more Lewis base compounds (e) are used as co-catalysts. From the viewpoint of reaction temperature, it is desirable for the Lewis base compound (e) to have a boiling point of reaction temperature or higher. Specific examples of the Lewis base compound (e) include the following compounds: 1) ester-based compounds such as propyl acetate, butyl acetate, phenyl acetate, and methyl propionate; 2) thioester-based compounds such as methyl mercaptopropionic acid and ethyl mercaptopropionic acid; 3) ketone-based compounds such as methyl isobutyl ketone and benzophenone; 4) amine-based compounds such as methylamine, ethylamine, propylamine, butylamine, cyclohexylamine, methylethylamine, dimethylamine, diethylamine, dipropylamine, and dibutylamine; 5) ether-based compounds such as diethyl ether and tetrahydrorane; 6) thioether-based compounds such as diethyl sulfide and diphenyl sulfide; and 7) phosphine-based compounds such as tripropyl phosphine, tributyl phosphine, trihexyl phosphine, tricyclohexyl phosphine, trioctyl phosphine, vinyl phosphine, propenyl phosphine, cyclohexenyl phosphine, dialkenyl phosphine, and trialkenyl phosphine. Among these, in terms of their synergistical action with the Lewis acid catalyst (d) to facilitate control of polymerization rate and molecular weight distribution of the polymer, one or more compounds selected from the group consisting of an ester-based compound, a ketone-based compound, and an ether-based compound are preferred, with an ester-based compound and a ketone-based compound being more preferably used. These Lewis base compounds (e) can be used singly or in combination of two or more thereof.

The Lewis base compound (e), which coordinates with the Lewis acid catalyst (d) that is a counter anion, and controls an interaction between a carbocation that is an active species and a counter anion, upon a polymerization reaction, adjusts a relative reaction frequency between the monomers (a) and (b), which also function as chain transfer agents. Usually, addition of the Lewis base compound (e) strengthens an interaction between a carbocation that is an active species and a counter anion, and therefore inhibits an excessive insertion reaction of the monomers (a) and (b), and facilitates a chain transfer reaction after the insertion reaction of the monomers (a) and (b), making it easier to control a molecular weight.

The amount of the Lewis base compound (e) is preferably 1.0 to 1,000 mol, more preferably 5.0 to 500 mol, and particularly preferably 10 to 200 mol, relative to 100 mol of the total of all monomer components. The amount below the lower limit of the above range leads to a too high polymerization rate, making it difficult to control a molecular weight. The amount exceeding the upper limit of the above range, on the other hand, reduces a monomer concentration and thereby reduces the amount of copolymer obtained, causing poor production efficiency.

A compounding proportion of the Lewis acid catalyst (d) to the Lewis base compound (e) is, in terms of the ratio (d/e) of the Lewis acid catalyst/Lewis base compound, preferably 1 to 30×10⁻³ (mol/mol) and more preferably 3 to 20×10⁻³ (mol/mol)

Next, the curable resin composition of the present invention will be described.

The curable resin composition of the present invention contains the soluble polyfunctional vinyl aromatic copolymer of the present invention and a radical polymerization initiator (radical polymerization catalyst) as essential components.

The radical polymerization initiator can be any known substance for use, and is not particularly limited, and can be a peroxide-based or an azo-based compound for use. Examples thereof include peroxides such as benzoyl peroxide, cumene hydroperoxide, 2,5-dimethylhexane-2,5-dihydroperoxide, 2,5-dimethyl-2,5-di(t-butylperoxy)hexyne-3, di-t-butyl peroxide, t-butylcumyl peroxide, α, α′-bis(t-butylperoxy-m-isopropyl)benzene, 2,5-dimethyl-2,5-di(t-butylperoxy)hexane, dicumyl peroxide, di-t-butylperoxyisophthalate, t-butylperoxybenzoate, 2,2-bis(t-butylperoxy)butane, 2,2-bis(t-butylperoxy)octane, 2,5-dimethyl-2,5-di(benzoylperoxy)hexane, di(trimethylsilyl)peroxide, and trimethylsilyltriphenylsilylperoxide, azo compounds such as 2,2′-azobis(isobutyronitrile), 4,4′-azobis(3,3,4,4,5,5,6,6,7,7,8,8,8-tridecafluorooctyl-4-cyano pentanoic acid), 2,2′-azobis(2,4,4-trimethylpentane), dimethyl-2,2′-azobis(2-methylpropionic acid), 2,2′-azobis(2-methylbutyronitrile), 1,1′-azobis(cyclohexane-1-carbonitrile), 2,2′-azobis(N-butyl-2-methylpropionamide), 2,2′-azobis[N-(2-carboxyethyl)-2-methylpropionamidine]tetrahydrate, as well as 2,3-dimethyl-2,3-diphenylbutane. They can be used singly or in combination of two or more thereof.

Within the range of the amount of radical polymerization initiator compounded of 0.01 to 10 parts by weight relative to 100 parts by weight of the soluble polyfunctional vinyl aromatic copolymer, a reaction will proceed smoothly without inhibiting a curing reaction.

The curable resin composition of the present invention may contain a thermosetting compound and/or a thermoplastic resin other than the soluble polyfunctional vinyl aromatic copolymer, if necessary.

The thermosetting compound refers to a resin having a reactive substituent or a cross-linking agent with a low molecular weight, and as the reactive substituent, a compound having an unsaturated carbon-carbon double bond is particularly suitable from the viewpoint of dielectric properties. Examples of the thermosetting resin include a vinyl ester resin, a polyvinylbenzyl resin, an unsaturated polyester resin, a curable vinyl resin, a diisopropenylbenzene resin, an allyl ether resin, a maleimide resin, an epoxy resin, a polycyanate resin, a phenolic resin, a benzocyclobutene resin, and one or more vinyl compounds having one or more polymerizable unsaturated hydrocarbon groups in a molecule. Representative examples of the thermosetting cross-linking agent include 1,4-divinylbenzene, 1,3-divinylbenzene, trivinylbenzene, divinylnaphthalene, 1,2-bis(4-vinylphenyl)ethane, triallyl cyanurate, and triallyl isocyanurate.

Examples of the thermoplastic resin include polystyrene, a polyphenylene ether resin, a polyetherimide resin, a polyethersulfone resin, a PPS resin, a polycyclopentadiene resin, and a polycycloolefin resin, known thermoplastic elastomers such as a styrene-ethylene-propylene copolymer, a styrene-ethylene-butylene copolymer, a styrene-butadiene copolymer, a styrene-isoprene copolymer, a hydrogenated styrene-butadiene copolymer, and a hydrogenated styrene-isoprene copolymer, or rubbers such as polybutadiene and polyisoprene.

The curable resin composition of the present invention can further contain, a cross-linking auxiliary agent. The cross-linking auxiliary agent is a liquid or solid compound with low viscosity when melted, containing two or more unsaturated bonds in the molecule, and is added for the purpose of raising a cross-linking density of a cured resin composition to impart heat resistance or adjusting a melt viscosity. Examples of the cross-linking auxiliary agent include, but are not limited to, divinylbenzene, trivinylbenzene, 2-vinylnorbornene, bisvinylphenylethane, divinylnaphthalene, 1,3-diisopropenylbenzene, triallyl cyanurate, and a polyfunctional methacrylate. The divinyl aromatic compound, which is essential as a raw material for the copolymer of the present invention, can also be used as an additive.

The curable resin composition of the present invention can contain an inorganic filler. As specific examples of the inorganic filler, commercially available fused silica, crystalline silica, alumina, silicon nitride, aluminum nitride, and the like can be used. Also, a filler in which a hydroxyl group on a surface of the filler is reduced by controlling a firing condition or the like during a production step, and a filler in which a hydroxyl group on a surface of the filler is reduced by bonding the hydroxyl group with a silane coupling agent or the like to improve adhesiveness to a resin, can be suitably used, but are not limited to the examples included here. Adding the inorganic filler to the composition enables thermal expansion of the composition to be reduced, and when the composition is used for circuit board applications, a difference in thermal expansion between a resin and a metal wiring layer is reduced, making it possible to prevent problems such as circuit breakage upon use.

As other types of inorganic fillers, compounding high dielectric powder such as barium titanate, or an inorganic magnetic material such as ferrite enables obtaining a resin composition suitable as a material for electronic components, particularly as a material for high-frequency electronic components.

The curable resin composition of the present invention can also be compounded with a flame retardant. As the flame retardant, a wide variety of known flame retardants can be used, including a bromine-based flame retardant, a phosphate-based flame retardant, a phosphazene-based flame retardant, and a phosphinate-based flame retardant, and a reactive flame retardant having a reactive substituent in the molecule such as an unsaturated group or an epoxy group.

The curable resin composition of the present invention can also be compounded with other additives, if necessary, such as a radical polymerization initiator (radical polymerization catalyst), antifoaming agents such as a silicone-based antifoaming agent and an acrylate-based antifoaming agent, a heat stabilizer, an antistatic agent, an ultraviolet absorber, a dye or a pigment, a lubricant, a dispersant such as a wetting dispersant, and the like.

The curable resin composition of the present invention can be used as a resin varnish, a cured product, a film, a composite material, a laminated plate, a metal plate with a resin, and the like. They are mainly applied to circuit board materials, and specific examples of their applications include a printed wiring board, a printed circuit board, a flexible printed wiring board, and a build-up wiring board.

When preparing a resin varnish, the curable composition of the present invention is dissolved in an organic solvent to prepare the resin varnish. The organic solvent is not particularly limited as long as it dissolves the curable resin composition and does not inhibit a curing reaction, and known organic solvents can be used. Examples thereof include aromatic hydrocarbon solvents such as toluene and xylene, ketones such as acetone, methyl ethyl ketone, and methyl isobutyl ketone, ethers such as tetrahydrofuran and dioxolane, esters such as ethyl acetate, propyl acetate, and butyl acetate, and polar solvents such as dimethylacetamide, and these can be used singly or in combination of two or more thereof.

Upon preparation of resin varnish, the amount of organic solvent used is, for example, in the range of 10 to 1,000 parts by weight relative to 100 parts by weight of the curable composition of the present invention.

A cured product obtained by curing a curable composition containing the soluble polyfunctional vinyl aromatic copolymer of the present invention can be used as a molded product, a laminated product, a cast product, an adhesive, a coating film, or a film. For example, a cured product of a semiconductor encapsulation material is a cast product or a molded product, and a method for obtaining a cured product for such applications is a method for casting a curable composition or forming it using a transfer molding machine, an injection molding machine, or the like, and then further heating it at, for example, 70 to 230 °C for 0.5 to 10 hours to enable obtaining a cured product.

The curable resin composition of the present invention can be formed into a curable composite material together with a base material. The curable composite material can be obtained by impregnating a base material with a resin varnish in which a curable composition is uniformly dissolved or dispersed in an organic solvent, by immersion or coating, followed by heating and drying. The curable composite material is also called a prepreg.

The base material mainly refers to, for example, a fiber or paper, which can be impregnated with a resin and which has enhanced mechanical strength and improved dimensional stability after curing. As the base material, a wide variety of known materials can be utilized, and examples include, but are not limited to, various glass cloths such as roving cloth, cloth, a chopped mat, and a surfacing mat, asbestos cloth, metal fiber cloth, other synthetic or natural inorganic fiber cloths, woven or nonwoven fabrics obtained from liquid crystal fibers such as a fully aromatic polyamide fiber, a fully aromatic polyester fiber, and a polybenzazole fiber, woven or nonwoven fabrics obtained from synthetic fibers such as a polyvinyl alcohol fiber, a polyester fiber, and an acrylic fiber, natural fiber cloths such as cotton cloth, linen cloth, and felt, carbon fiber cloth, craft paper, cotton paper, cloths or papers, such as natural cellulose-based cloth such as paper-glass mixed fiber paper, which can be used singly or in combination of two or more thereof. Examples of a glass cloth material include E glass, NE glass, L glass, and Q glass, and in particular those that have been subjected to treatment whereby a hydroxyl group on a glass surface is reduced and adhesiveness between a glass fiber surface and a resin is improved, are suitable for circuit board applications aimed at high-speed communication.

The amount of base material used in the curable composite material can be appropriately selected depending on the purpose, for example, within the range of 5 to 90 wt %. A base material in an amount of less than 5 wt % results in a composite material having insufficient dimensional stability and strength after curing, and a base material in an amount of more than 90 wt % results in a composite material having poor dielectric properties, which are not preferable. In order to improve adhesiveness at an interface between a resin and a base material, the curable composite material can be used with a coupling agent such as a silane coupling agent, a titanate coupling agent, an aluminum-based coupling agent, or a zircoaluminate coupling agent, if necessary.

A cured composite material can be obtained by curing the curable composite material by a method such as heating. The method for producing it is not particularly limited, and for example, plural sheets of the curable composite material are overlapped followed by simultaneous bonding and heat curing of each layer under heat and pressure to enable obtaining a cured composite material of a desired thickness. Also, a cured composite material that has been bonded and cured once is combined with a curable composite material to enable obtaining a cured composite material with a new layer configuration. Laminate forming and curing are usually performed simultaneously using a heat press or the like, but both may be performed separately. In other words, an uncured or semi-cured composite material preliminarily obtained by laminate forming can be cured by heat treatment or another method.

Forming and curing can be performed, for example, in an inert gas atmosphere at a temperature of 80 to 300 °C, at a pressure of 0.1 to 1000 kg/cm² for a time of 1 minute to 10 hours.

The laminate of the present invention is composed of a cured composite material layer and a metal foil layer, and may be used with an adhesive, if necessary. Examples of the metal foil include copper foil and aluminum foil, with a thickness in the range, for example, of 1 to 200 μm.

The curable composition of the present invention can also be formed into a film having a thickness of, for example, 1 to 200 μm.

### EXAMPLES

The present invention will be described in detail below with reference to examples, but the present invention is not limited to these examples. It is to be noted that all parts in each example refer to parts by weight, and physical properties were measured by the methods shown below.

### 1) Molecular Weight and Molecular Weight Distribution of Copolymer (Soluble Polyfunctional Aromatic Copolymer)

A molecular weight and a molecular weight distribution were measured using GPC. Specifically, a main body (HLC-8320 GPC manufactured by Tosoh Corporation) equipped with columns (TSKgel G4000HXL, TSKgel G3000HXL, and TSKgel G2000HXL, manufactured by Tosoh Corporation) in series was used, and a column temperature was set to 40 °C. Tetrahydrofuran (THF) was used as an eluent, with a flow rate of 1 mL/min, and a differential refractive index detector was used as a detector. As a measurement sample, 0.05 g of a sample were dissolved in 10 mL of THF and filtered through a microfilter, and 50 μL of the sample was used. Conversion was made using a calibration curve obtained by standard monodisperse polystyrenes (A-500, A-1000, A-2500, A-5000, F-1, F-2, F-4, F-10, F-20, F-40, F-80, and F-128, manufactured by Tosoh Corporation).

### 2) Copolymer Structure

A copolymer structure was determined by 13C-NMR and 1H-NMR analysis using a JNM-ECZ400R/S1 nuclear magnetic resonance spectrometer manufactured by JEOL RESONANCE Inc. Chloroform-d1 was used as a solvent, and the peak observed at 7.25 ppm in chloroform was used as an internal standard.

### 3) Analysis of Unsaturated Functional Substituent

The amount of unsaturated functional substituent in the copolymer was quantified by combining a plurality of measurement methods. The measurement methods used will be described below. The amount of each monomer consumed upon polymerization was measured using a GC-2010 gas chromatograph measuring apparatus manufactured by Shimadzu Corporation, with 4-acetylbiphenyl as an internal standard material, and the ratio of each monomer component in the copolymer was calculated from the amount of monomer consumed upon polymerization. Furthermore, a number-average molecular weight was analyzed using the results of the GPC analysis described above. A content ratio of a constituent unit of the copolymer, such as a vinyl group or a 1,2-substituted ethylene group, was determined by 13C-NMR and 1H-NMR analysis using a JNM-ECZ400R/S1 nuclear magnetic resonance spectrometer manufactured by JEOL RESONANCE Inc. Chloroform-d1 was used as a solvent, and the peak observed at 7.25 ppm in chloroform was used as an internal standard.

### 4) Measurement of Vinyl Equivalent

The vinyl equivalent of the copolymer was measured by iodine value measurement using the Wijs method. First, 0.3 g of solid content of a sample was weighed into an Erlenmeyer flask and diluted with 20 ml of toluene. 25 ml of a commercially available 0.1 mol/L Wijs reagent (iodine monochloride-acetic acid solution) was weighed out and added to this solution, using a volumetric pipette, and left to stand in a dark place for 30 minutes after stirring. To this solution were added a 20% by mass potassium iodide aqueous solution and 100 ml of pure water, and the solution was vigorously stirred, then transferred to a beaker, and titrated with a 0.1 mol/l sodium thiosulfate aqueous solution using an automatic titrator (with a composite electrode PT-301 used, manufactured by HIRANUMA Co., Ltd.) to calculate an iodine value using the following Expression 3.

Iodine value (g/100)=(B−A)×F×1.269/sample amount (g) [Expression 3]

### Herein,

A: a titration amount (cc) of a 0.1 mol/L sodium thiosulfate aqueous solution required for neutralization,
B: a titration amount (cc) of a 0.1 mol/L sodium thiosulfate aqueous solution required for blank measurement,
F: a titer of a 0.1 mol/L sodium thiosulfate aqueous solution.

Based on the iodine value thus determined, the vinyl equivalent was calculated using the following expression 4.

Vinyl equivalent (g/eq.)=100×253.81/iodine value [Expression 4]

### 5) Measurement of Halogen Element Content

The content of each element of chlorine, bromine, and iodine, was measured by combustion ion chromatography. An apparatus for use was a Dionex Aquion Ion Chromatography System manufactured by Thermo Fisher Scientific Inc. The lower detection limit of this method is 5 ppm.

### 6) Measurement of Coefficient of Linear Thermal Expansion (CTE) of Cured Product

A surface of a polyethylene terephthalate film was uniformly coated with the copolymer composition varnish, and the coated film was heated in an oven at 125 °C for 10 minutes and dried. The dried material on the film was peeled off, pulverized into powder, and placed in a fluororesin forming frame of 1 mm thickness, raised to a temperature of 210 °C under a reduced pressure, and further heat-treated at 210 °C for 120 minutes under a pressure of 2.0 MPa to cure the copolymer composition. The formed product was allowed to cool to room temperature and then removed. The resulting test piece was set in a TMA (thermomechanical analyzer) and scanned in compression mode from 30 °C to 320 °C at a rate of temperature rise of 5 °C/min under a nitrogen stream, to determine the coefficient of linear thermal expansion (CTE) from a slope of a temperature-elongation curve from 130 °C to 150 °C.

A glass transition temperature was measured by setting the above-described test piece in a DMA (dynamic mechanical analyzer) measuring apparatus and scanning in three-point bending measurement mode from 30 °C to 320 °C at a rate of temperature rise of 2 °C/min under a nitrogen stream, to determine Tg from the temperature of the peak top of a tan 6 curve.

### 7) Minimum Melt Viscosity (η1) and η2

A surface of a polyethylene terephthalate film was uniformly coated with the copolymer composition varnish, and the coated film was heated in an oven at 125 °C for 10 minutes and dried. The dried material on the film was peeled off and pulverized, and the powdered sample was set on a rheometer. A temperature-viscosity curve was then measured using a parallel plate method. From the obtained graph, the viscosity at the point where viscosity was reduced most was determined as the minimum melt viscosity (η1), and the viscosity at the point 5 °C higher than the temperature at which η1 was observed was determined as η2. The rheometer used was a HAAKE RheoStress 600 manufactured by Thermo Fisher Scientific Inc.

### 8) Resin Flowability Test

Measurement was made according to JIS C 6521. Press conditions of this measurement were 210 °C and 1.38 MPa.

### 9) Evaluation of Adhesion Reliability

A change in adhesiveness was measured and evaluated before and after HAST (Highly Accelerated Temperature and Humidity Stress Test). Specifically, the procedure is as follows.

### (i) Preparation of Evaluation Board

### <Evaluation of Adhesiveness>

Adhesiveness was evaluated by measuring copper foil peel strength according to the following procedure.

### <Fabrication of Evaluation Board>

### (1) Surface Treatment of Copper Foil

A shiny side of a “3EC-III” (electrolytic copper foil, 35 μm, manufactured by MITSUI MINING & SMELTING CO., LTD.) was etched 1 μm with “CZ8101” manufactured by MEC COMPANY LTD. to undergo roughening treatment of its copper surface followed by anti-rust treatment (CL8300). This copper foil is called CZ copper foil. It was further heat-treated in an oven at 130 °C for 30 minutes. By such treatment, an inner layer substrate was obtained.

### (2) Preparation of Inner Layer Substrate

Both sides of a glass cloth base epoxy resin double-sided copper-clad laminate (“R1515A” with a copper foil thickness of 18 μm and a substrate thickness of 0.4 mm, manufactured by Panasonic Co., Ltd.), inside of which an inner layer circuit was formed, were etched 1 μm with “CZ8101” manufactured by MEC COMPANY LTD. to undergo roughening treatment of the copper surfaces. By such treatment, CZ copper foil with treated surfaces was obtained.

### (3) Preparation of Resin Sheet

As a support, a polyethylene terephthalate film with a release layer (“1-V4” with a thickness of 50 μm, manufactured by Nippa Co., Ltd.) was prepared. A surface of the release layer of this support was uniformly coated with each of the resin varnishes described in Examples and Comparative Examples, which was prepared by the method described below, so that a thickness of a resin composition layer after drying was 25 μm. Thereafter, the resin varnish was dried at 90 °C to 130 °C (average 110 °C) for 5 minutes followed by removal of solvent, to obtain a resin sheet including the support and the resin composition layer.

### (4) Lamination of Resin Composition Layer

The resin sheet with the support prepared as described above was laminated on both sides of the inner layer substrate so that the resin composition layer was in contact with the inner layer substrate. The lamination was performed by reducing pressure for 60 seconds using a batch-type vacuum laminating apparatus to adjust an air pressure to 15 hPa or less, and then pressing them at 125 °C and a pressure of 0.70 MPa for 30 seconds. Next, a heat press was performed at 100 °C and a pressure of 0.5 MPa for 60 seconds. The support was then peeled off to expose the resin composition layer.

### (5) Lamination of Copper Foil and Curing of Resin Composition Layer

The CZ copper foil with treated surfaces was laminated on the exposed resin composition layer under the same conditions as above. Then, the resin composition layer was cured under curing conditions of 200 °C and 90 minutes to form a cured product (insulating layer). As a result, an evaluation board with the CZ copper foil laminated on both sides was obtained.

### <Measurement of Copper Foil Peel Strength Before HAST>

The evaluation board fabricated was cut into small pieces of 150 mm×30 mm. A cutter was used to make a cut of 10 mm wide and 100 mm long in a copper foil portion of the small piece, and one end thereof was peeled off and held with a grip of the tensile tester described below. At room temperature (normal temperature), a load [N/mm] was measured when it was peeled off vertically by 35 mm at a rate of 50 mm/min. The load value obtained from this measurement is determined as the “copper foil peel strength before HAST.” For the measurement, a tensile tester (universal testing machine “Autograph EZ-S-50N” manufactured by Shimadzu Corporation) was used. The measurement was made in accordance with the Japanese Industrial Standards JIS C6481. The results are shown in Table 1, with results of copper foil peel strength before HAST of 0.40 N/mm or more scored “◯” and results of less than 0.4 N/mm scored “x”.
<Measurement of Copper Foil Peel Strength after HAST>

Using a high accelerated stress test chamber (“PC-242HS-A” manufactured by Hirayama Manufacturing Corporation), an accelerated environmental test was conducted on the evaluation board fabricated for 100 hours under elevated temperature and high humidity conditions of 130 °C and 85% RH. Thereafter, a cut was made in the evaluation board after HAST in the same manner as described above, and one end of the cut piece was peeled off in the same manner as in the above-described measurement and held with a grip of the tensile tester described above, and a load [N/mm] at room temperature (normal temperature) was measured when the cut piece was peeled off vertically by 35 mm at a rate of 50 mm/min. The load value obtained from this measurement is determined as the “copper foil peel strength after HAST.” The measurement was made in accordance with the Japanese Industrial Standards JIS C6481. The results are shown in Table 1, with results of the difference between the copper foil peel strength before HAST and that after HAST of less than 0.1 N/mm scored “O” and results of 0.1 N/mm or more scored “X”.

The compounds described in Examples listed below are as follows.
Copolymers A, B, C, and D: Those as described in Examples described later
Thermosetting compound E-1: DVB-630 (mixture of 1,4-divinylbenzene, 1,3-divinylbenzene, 1,4-ethylvinylbenzene, and 1,3-ethylvinylbenzene, manufactured by NIPPON STEEL Chemical & Material Co., Ltd.)
Thermosetting compound E-2: OPE-2St (polyphenylene ether resin with an end modified with vinylbenzyl ether, manufactured by Mitsubishi Gas Chemical Company, Inc.)
Thermoplastic resin F: Tuftec H1043 (hydrogenated styrene-based thermoplastic elastomer, manufactured by Asahi Kasei Corporation)
Polymerization initiator G: PERBUTYL P (1,3-bis(butylperoxyisopropyl)benzene, manufactured by NOF CORPORATION)
Stabilizer H: ADK STAB AO-60 (tetrakis[methylene-3-(3′,5′-di-t-butyl-4-hydroxyphenyl)propionate]methane, manufactured by ADEKA Corporation)
Inorganic filler I: SE2050 SPE, (amorphous spherical silica treated with a phenyl silane coupling agent, with an average particle size of 0.5 μm, manufactured by Admatechs Co., Ltd.)

### Example 1

A 1.0 L reactor was charged with 0.57 mol (81.4 mL) of divinylbenzene (having a structural formula shown below and being a mixture of 1,4-divinylbenzene and 1,3-divinylbenzene, and the same applies to the following examples.),

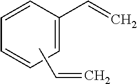

0.34 mol (47.8 mL) of ethylvinylbenzene (having a structural formula shown below and being a mixture of 1-ethyl-4-vinylbenzene and 1-ethyl-3-vinylbenzene, and the same applies to the following examples.),

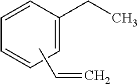

1.95 mol (224.3 mL) of styrene (the structural formula is shown below.),

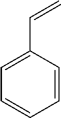

and 2.99 mol (344.4 mL) of n-propyl acetate, and the mixture was heated. In a state where a temperature had risen to 100 °C, 23 mmol of a boron trifluoride diethyl ether complex was added and reacted for 3.5 hours.

To the polymerization solution was added 166 ml of a 7% sodium hydrogencarbonate aqueous solution to quench the reaction, and then the oil layer was extracted and washed three times with pure water. The reaction solution was poured into a large amount of methanol to recover the resulting white precipitate, and the resulting polymer was weighed, confirming that 165.3 g of a copolymer A-1 was obtained.

The copolymer A-1 obtained was analyzed by GPC, resulting in a copolymer A-1 having an Mn of 1,200, an Mw of 10,500, and an Mw/Mn of 8.75. The vinyl equivalent of the copolymer A-1 was measured to be 410 (g/eq.), and the number of unsaturated bond functional groups was calculated to be 2.93 from (Expression 1).

From the results of GC analysis, each structure included in the copolymer was calculated as follows.
The structural unit derived from divinylbenzene (a): 31.0 mol % (34.9 wt %)
The structural unit derived from ethylvinylbenzene (b-1): 12.9 mol % (14.7 wt %)
The structural unit derived from styrene (b-2): 56.1 mol % (50.4 wt %)

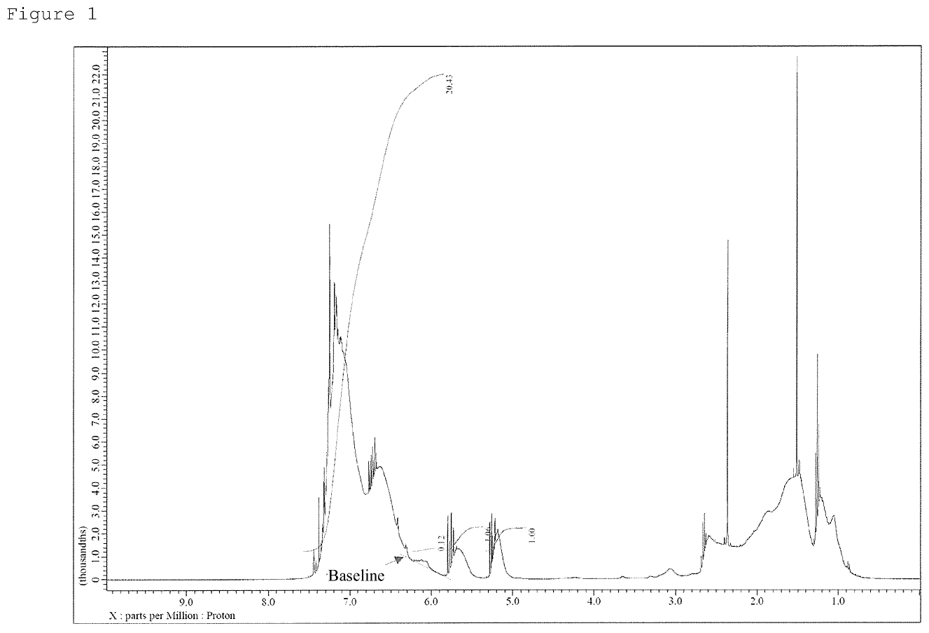

A 1H-NMR chart of the copolymer A-1 is shown in FIG. 1. As a result of 1H-NMR analysis, the resonance lines assigned to vinyl groups contained in (a1) and (ta1) were observed at 4.83-5.33 ppm and 5.37-5.82 ppm, and one hydrogen atom in this structure was normalized as an integrated value of 1. It is to be noted that the integrated value by 1H-NMR analysis in Example 1 is a value based on this normalization.

The resonance lines assigned to aromatic rings in the structural units derived from the (a), (b-1), and (b-2) were observed at 5.84-7.57, with the total integrated value of 20.31.

Furthermore, the resonance lines assigned to 1,2-substituted ethylene groups of (ta1), (ta2), and (tb1) were observed at 5.95-6.23. Since the resonance lines overlapped with the resonance lines assigned to aromatic rings of (a), (b-1), and (b-2), the baseline shown in FIG. 1 was used to determine an integrated value of only a portion observed as a shoulder from the resonance lines assigned to the aforementioned aromatic rings. As a result, the integrated value was determined to be 0.12.

From the ratio of the integrated values, the proportion of the unsaturated bond functional groups derived from vinyl groups contained in (a1) and (ta1) relative to the number of unsaturated bond functional groups was calculated to be 89.3 mol %, and the proportion of the unsaturated bond functional groups derived from 1,2-substituted ethylene groups contained in (ta1), (ta2), and (tb1) was calculated to be 10.7 mol %. From (Expression 2), the functional group equivalent of the 1,2-substituted ethylene groups was calculated to be 3,827 (g/eq.).

The copolymer A-1 was soluble in toluene, xylene, tetrahydrofuran, dichloroethane, or chloroform, and no observable gel was generated.

The resulting analysis of each element of chlorine, bromine, and iodine demonstrated that each content was below the lower detection limit (5 ppm).

According to the compounding composition (parts by weight) described in Table 1, the copolymer A-1, toluene as a solvent, the polymerization initiator G, and the stabilizer H were added and mixed using a shaker to obtain a copolymer composition varnish of a copolymer A-1.

The obtained copolymer composition varnish was used to measure physical properties according to the procedures described in each of the test methods described above. The obtained results are summarized in Table 1.

### Example 2

A 1.0 L reactor was charged with 0.61 mol (86.9 mL) of divinylbenzene, 0.36 mol (51.0 mL) of ethylvinylbenzene, 2.08 mol (239.3 mL) of styrene, and 3.18 mol (419.0 mL) of n-butyl acetate and heated. In a state where a temperature was raised to 110 °C, 25 mmol of a boron trifluoride diethyl ether complex was added and reacted for 2.5 hours.

To the polymerization solution was added 177 ml of a 7% sodium hydrogencarbonate aqueous solution to quench the reaction, and then the oil layer was extracted and washed three times with pure water. The reaction solution was poured into a large amount of methanol to recover the resulting white precipitate, and the resulting polymer was weighed, confirming that 258.5 g of a copolymer A-2 was obtained.

The copolymer A-2 obtained was analyzed by GPC, resulting in a copolymer A-2 having an Mn of 930, an Mw of 9,500, and an Mw/Mn of 10.2. The vinyl equivalent of the copolymer A-2 was measured to be 380 (g/eq.), and the number of unsaturated bond functional groups was calculated to be 2.45 from (Expression 1).

From the results of GC analysis, each structure included in the copolymer was calculated as follows.
The structural unit derived from divinylbenzene (a): 28.8 mol % (32.6 wt %)
The structural unit derived from ethylvinylbenzene (b-1): 13.1 mol % (15.0 wt %)
The structural unit derived from styrene (b-2): 58.1 mol % (52.4 wt %)

Also, a 1H-NMR analysis was carried out in the same manner as for the copolymer A-1, and the obtained resonance lines were observed in the same range as for the copolymer A-1.

The resonance lines assigned to aromatic rings in the structural units derived from the (a), (b-1), and (b-2) were observed at the same positions as in the copolymer A-1, and the total of the integrated values was 24.58.

Furthermore, the resonance lines assigned to 1,2-substituted ethylene groups of (ta1), (ta2), and (tb1) were also observed at the same positions as in the copolymer A-1, and as a result of analysis in the same manner as in Example 1, the integrated value was determined to be 0.17.

From the ratio of the above integrated values, the proportion of the unsaturated bond functional groups derived from vinyl groups contained in (a1) and (ta1) to the number of unsaturated bond functional groups was calculated to be 85.5 mol %, and the proportion of the unsaturated bond functional groups derived from 1,2-substituted ethylene groups contained in (ta1), (ta2), and (tb1) was calculated to be 14.5 mol %. From (Expression 2), the functional group equivalent of the 1,2-substituted ethylene groups was calculated to be 2,615 (g/eq.).

The copolymer A-2 was soluble in toluene, xylene, tetrahydrofuran, dichloroethane, or chloroform, and no observable gel was generated.

The resulting analysis of each element of chlorine, bromine, and iodine demonstrated that each content was below the lower detection limit (5 ppm).

### Example 3

A 1.0 L reactor was charged with 0.47 mol (67.0 mL) of divinylbenzene, 0.28 mol (39.3 mL) of ethylvinylbenzene, 1.60 mol (184.4 mL) of styrene, and 3.51 mol (403.3 mL) of n-propyl acetate and heated. In a state where a temperature was raised to 90 °C, 48 mmol of a boron trifluoride diethyl ether complex was added and reacted for 1.5 hours.

To the polymerization solution was added 171 ml of a 7% sodium hydrogencarbonate aqueous solution to quench the reaction, and then the aqueous phase was removed by liquid separation, and 171 ml of a 7% sodium hydrogencarbonate aqueous solution was added thereto again, followed by stirring for 30 minutes. Thereafter, the oil layer was extracted and washed three times with pure water. The reaction solution was poured into a large amount of methanol to recover the resulting white precipitate, and the resulting polymer was weighed, confirming that 359 g of a copolymer A-3 was obtained.

The copolymer A-3 obtained was analyzed by GPC, resulting in a copolymer A-3 having an Mn of 1,400, an Mw of 12,500, and an Mw/Mn of 8.93. The vinyl equivalent of the copolymer A-3 was measured to be 398 (g/eq.), and the number of unsaturated bond functional groups was calculated to be 3.52 from (Expression 1).

From the results of GC analysis, each structure included in the copolymer was calculated as follows.
The structural unit derived from divinylbenzene (a): 26.2 mol % (29.4 wt %)
The structural unit derived from ethylvinylbenzene (b-1): 12.1 mol % (13.8 wt %)
The structural unit derived from styrene (b-2): 63.1 mol % (56.8 wt %)

Also, a 1H-NMR analysis was carried out in the same manner as for the copolymer A-1, and the obtained resonance lines were observed in the same range as for the copolymer A-1.

The resonance lines assigned to aromatic rings in the structural units derived from the (a), (b-1), and (b-2) were observed at the same positions as in the copolymer A-1, and the total of the integrated values was 22.03.

Furthermore, the resonance lines assigned to 1,2-substituted ethylene groups of (ta1), (ta2), and (tb1) were also observed at the same positions as in the copolymer A, and as a result of analysis in the same manner as in Example 1, the integrated value was determined to be 0.09.

From the ratio of the above integrated values, the proportion of the unsaturated bond functional groups derived from vinyl groups contained in (a1) and (ta1) to the number of unsaturated bond functional groups was calculated to be 91.7 mol %, and the proportion of the unsaturated bond functional groups derived from 1,2-substituted ethylene groups contained in (ta1), (ta2), and (tb1) was calculated to be 8.26 mol %. From (Expression 2), the functional group equivalent of the 1,2-substituted ethylene groups was calculated to be 4,820 (g/eq.).

The copolymer A-3 was soluble in toluene, xylene, tetrahydrofuran, dichloroethane, or chloroform, and no observable gel was generated.

The resulting analysis of each element of chlorine, bromine, and iodine demonstrated that each content was below the lower detection limit (5 ppm).

### Comparative Example 1

A 1.0 L reactor was charged with 0.60 mol (85.5 ml) of divinylbenzene, 0.36 mol (51.3 ml) of ethylvinylbenzene, 2.04 mol (234.5 ml) of styrene, and 3.00 mol (345.0 ml) of n-propyl acetate and added with 120 mmol of a boron trifluoride diethyl ether complex at 70 °C, and the mixture was reacted for 4 hours. The polymerization solution was quenched with a 7% sodium hydrogencarbonate aqueous solution, and then the oil layer was washed three times with pure water. The reaction solution was poured into a large amount of methanol to recover the resulting white precipitate, and the resulting polymer was weighed, confirming that 179.3 g of a copolymer B-1 was obtained.

The copolymer B-1 obtained was analyzed by GPC, resulting in a copolymer B-1 having an Mn of 3,020, an Mw of 40,500, and an Mw/Mn of 13.41. The vinyl equivalent of the copolymer B-1 was measured to be 445 (g/eq.), and the number of unsaturated bond functional groups was calculated to be 6.79 from (Expression 1).

From the results of GC analysis, each structure included in the copolymer was calculated as follows.
The structural unit derived from divinylbenzene (a): 29.3 mol % (33.1 wt %)
The structural unit derived from ethylvinylbenzene (b-1): 12.4 mol % (14.2 wt %)
The structural unit derived from styrene (b-2): 58.3 mol % (52.7 wt %)

Also, a 1H-NMR analysis was carried out in the same manner as for the copolymer A-1, and the obtained resonance lines were observed in the same range as for the copolymer A-1.

The resonance lines assigned to aromatic rings in the structural units derived from the (a), (b-1), and (b-2) were observed at the same positions as in the copolymer A-1, and the total of the integrated values was 19.20.

Furthermore, the resonance lines assigned to 1,2-substituted ethylene groups of (ta1), (ta2), and (tb1) were also observed at the same positions as in the copolymer A, and as a result of analysis in the same manner as in Example 1, the integrated value was determined to be 0.083.

From the ratio of the above integrated values, the proportion of the unsaturated bond functional groups derived from vinyl groups contained in (a1) and (ta1) to the number of unsaturated bond functional groups was calculated to be 92.3 mol %, and the proportion of the unsaturated bond functional groups derived from 1,2-substituted ethylene groups contained in (ta1), (ta2), and (tb1) was calculated to be 7.70 mol %. From (Expression 2), the functional group equivalent of the 1,2-substituted ethylene groups was calculated to be 5,779 (g/eq.).

The copolymer B-1 was soluble in toluene, xylene, tetrahydrofuran, dichloroethane, or chloroform, and no observable gel was generated.

The resulting analysis of each element of chlorine, bromine, and iodine demonstrated that each content was below the lower detection limit (5 ppm).

### Comparative Example 2

A 1.0 L reactor was charged with 0.30 mol (42.7 ml) of divinylbenzene, 0.18 mol (25.1 ml) of ethylvinylbenzene, 2.52 mol (289.7 ml) of styrene, and 3.00 mol (345.0 ml) of n-propyl acetate and added with 120 mmol of a boron trifluoride diethyl ether complex at 70 °C, and the mixture was reacted for 4 hours. The polymerization solution was quenched with a 7% sodium hydrogencarbonate aqueous solution, and then the oil layer was washed three times with pure water. The reaction solution was poured into a large amount of methanol to recover the resulting white precipitate, and the resulting polymer was weighed, confirming that 164.2 g of a copolymer B-2 was obtained.

The copolymer B-2 obtained was analyzed by GPC, resulting in a copolymer B-2 having an Mn of 1,500, an Mw of 12,500, and an Mw/Mn of 8.33. The vinyl equivalent of the copolymer B-2 was measured to be 831 (g/eq.), and the number of unsaturated bond functional groups was calculated to be 1.81 from (Expression 1).

From the results of GC analysis, each structure included in the copolymer was calculated as follows.
The structural unit derived from divinylbenzene (a): 11.3 mol % (13.5 wt %)
The structural unit derived from ethylvinylbenzene (b-1): 5.81 mol % (7.06 wt %)
The structural unit derived from styrene (b-2): 82.9 mol % (79.4 wt %)

Also, a 1H-NMR analysis was carried out in the same manner as for the copolymer A-1, and the obtained resonance lines were observed in the same range as for the copolymer A-1.

The resonance lines assigned to aromatic rings in the structural units derived from the (a), (b-1), and (b-2) were observed at the same positions as in the copolymer A-1, and the total of the integrated values was 47.8.

Furthermore, the resonance lines assigned to 1,2-substituted ethylene groups of (ta1), (ta2), and (tb1) were also observed at the same positions as in the copolymer A, and as a result of analysis in the same manner as in Example 1, the integrated value was determined to be 0.29.

From the ratio of the above integrated values, the proportion of the unsaturated bond functional groups derived from vinyl groups contained in (a1) and (ta1) to the number of unsaturated bond functional groups was calculated to be 77.3 mol %, and the proportion of the unsaturated bond functional groups derived from 1,2-substituted ethylene groups contained in (ta1), (ta2), and (tb1) was calculated to be 22.7 mol %. From (Expression 2), the functional group equivalent of the 1,2-substituted ethylene groups was calculated to be 3,660 (g/eq.).

The copolymer B-2 was soluble in toluene, xylene, tetrahydrofuran, dichloroethane, or chloroform, and no observable gel was generated.

The resulting analysis of each element of chlorine, bromine, and iodine demonstrated that each content was below the lower detection limit (5 ppm).

### Comparative Example 3

A 1.0 L reactor was charged with 0.45 mol (64.1 ml) of divinylbenzene, 0.26 mol (37.6 ml) of ethylvinylbenzene, 2.28 mol (262.1 ml) of styrene, and 3.00 mol (345.0 ml) of n-propyl acetate and added with 120 mmol of a boron trifluoride diethyl ether complex at 70 °C, and the mixture was reacted for 4 hours. The polymerization solution was quenched with a 7% sodium hydrogencarbonate aqueous solution, and then the oil layer was washed three times with pure water. The reaction solution was poured into a large amount of methanol to recover the resulting white precipitate, and the resulting polymer was weighed, confirming that 172.2 g of a copolymer B-3 was obtained.

The copolymer B-3 obtained was analyzed by GPC, resulting in a copolymer B-3 having an Mn of 2,080, an Mw of 30,800, and an Mw/Mn of 14.8. The vinyl equivalent of the copolymer B-3 was measured to be 486 (g/eq.), and the number of unsaturated bond functional groups was calculated to be 4.28 from (Expression 1).

From the results of GC analysis, each structure included in the copolymer was calculated as follows.
The structural unit derived from divinylbenzene (a): 20.9 mol % (24.3 wt %)
The structural unit derived from ethylvinylbenzene (b-1): 9.10 mol % (10.7 wt %)
The structural unit derived from styrene (b-2): 70.0 mol % (65.0 wt %)

Also, a 1H-NMR analysis was carried out in the same manner as for the copolymer A-1, and the obtained resonance lines were observed in the same range as for the copolymer A-1.

The resonance lines assigned to aromatic rings in the structural units derived from the (a), (b-1), and (b-2) were observed at the same positions as in the copolymer A-1, and the total of the integrated values was 28.2.

Furthermore, the resonance lines assigned to 1,2-substituted ethylene groups of (ta1), (ta2), and (tb1) were also observed at the same positions as in the copolymer A-1, and as a result of analysis in the same manner as in Example 1, the integrated value was determined to be 0.10.

From the ratio of the above integrated values, the proportion of the unsaturated bond functional groups derived from vinyl groups contained in (a1) and (ta1) to the number of unsaturated bond functional groups was calculated to be 90.5 mol %, and the proportion of the unsaturated bond functional groups derived from 1,2-substituted ethylene groups contained in (ta1), (ta2), and (tb1) was calculated to be 9.45 mol %. From (Expression 2), the functional group equivalent of the 1,2-substituted ethylene groups was calculated to be 5,141 (g/eq.).

The copolymer B-3 was soluble in toluene, xylene, tetrahydrofuran, dichloroethane, or chloroform, and no observable gel was generated.

The resulting analysis of each element of chlorine, bromine, and iodine demonstrated that each content was below the lower detection limit (5 ppm).

### Comparative Example 4

A 1.0 L reactor was charged with 1.82 mol (259.6 mL) of divinylbenzene, 0.43 mol (60.9 mL) of ethylvinylbenzene, 0.28 mol (36.9 mL) of n-butyl acetate, and 140 mL of toluene, and added with a solution of 40 mmol of methanesulfonic acid dissolved in 0.12 mol (15.7 mL) of n-butyl acetate at 70 °C, and the mixture was reacted for 6 hours. The polymerization solution was quenched with calcium hydroxide, and then filtered using activated alumina as a filter auxiliary agent. The reaction solution was poured into a large amount of methanol to recover the resulting white precipitate, and the resulting polymer was weighed, confirming that 221.0 g of a copolymer C-1 was obtained.

The copolymer C-1 obtained was analyzed by GPC, resulting in a copolymer C-1 having an Mn of 1,090, an Mw of 12,300, and an Mw/Mn of 11.28. The vinyl equivalent of the copolymer C-1 was measured to be 193 (g/eq.), and the number of unsaturated bond functional groups was calculated to be 5.65 from (Expression 1).

From the results of GC analysis, each structure included in the copolymer was calculated as follows.
The structural unit derived from divinylbenzene (a): 84.0 mol % (83.8 wt %)
The structural unit derived from ethylvinylbenzene (b-1): 16.0 mol % (16.2 wt %)

Also, as a result of 1H-NMR analysis, the resonance lines assigned to vinyl groups contained in (a1) and (ta1) were observed at 5.02-5.38 ppm and 5.46-5.82 ppm. An integrated value was determined by analysis in the same manner as in Synthesis Example 1.

The resonance lines assigned to aromatic rings in the structural units derived from the (a) and (b-1) were observed at 5.90-7.62, with the total of the integrated values being 8.90.

The resonance lines assigned to 1,2-substituted ethylene groups of (ta1), (ta2), and (tb1) were also observed at 5.90-6.23. Since the resonance lines overlapped with the resonance lines assigned to aromatic rings of (a) and (b-1), an integrated value was determined in the same manner as in Example 1. As a result, the integrated value was determined to be 0.33.

From the ratio of the above integrated values, the proportion of the unsaturated bond functional groups derived from vinyl groups contained in (a1) and (ta1) to the number of unsaturated bond functional groups was calculated to be 75.4 mol %, and the proportion of the unsaturated bond functional groups derived from 1,2-substituted ethylene groups contained in (ta1), (ta2), and (tb1) was calculated to be 24.6 mol %. From (Expression 2), the functional group equivalent of the 1,2-substituted ethylene groups was calculated to be 783 (g/eq.).

The copolymer C-1 was soluble in toluene, xylene, tetrahydrofuran, dichloroethane, or chloroform, and no observable gel was generated.

The analysis of each element of chlorine, bromine, and iodine demonstrated that each content was below the lower detection limit (5 ppm).

### Comparative Example 5

A 1.0 L reactor was charged with 2.97 mol (423.0 mL) of divinylbenzene, 0.70 mol (99.2 mL) of ethylvinylbenzene, 0.33 mol (38.3 ml) of styrene, 0.13 mol (15.3 ml) of n-propyl acetate, and 330 mL of toluene, and added with a solution of 24 mmol of trifluoromethanesulfonic acid dissolved in 33 mmol of n-propyl acetate (3.8 mL) at 50 °C, and the mixture was reacted for 7 hours. The polymerization solution was quenched with a 7% sodium hydrogencarbonate aqueous solution, and then the oil layer was washed three times with pure water. The reaction solution was poured into a large amount of methanol to recover the resulting white precipitate, and the resulting polymer was weighed, confirming that 547.8 g of a copolymer C-2 was obtained.

The copolymer C-2 obtained was analyzed by GPC, resulting in a copolymer C-2 having an Mn of 950, an Mw of 13,100, and an Mw/Mn of 13.8. The vinyl equivalent of the copolymer C-2 was measured to be 158 (g/eq.), and the number of unsaturated bond functional groups was calculated to be 6.01 from (Expression 1).

From the results of GC analysis, each structure included in the copolymer was calculated as follows.
The structural unit derived from divinylbenzene (a): 83.1 mol % (84.1 wt %)
The structural unit derived from ethylvinylbenzene (b-1): 10.1 mol % (10.4 wt %)
The structural unit derived from styrene (b-2): 6.76 mol % (5.50 wt %)

Also, a 1H-NMR analysis was carried out in the same manner as for the copolymer A-1, and the obtained resonance lines were observed in the same range as for the copolymer A-1.

The resonance lines assigned to aromatic rings in the structural units derived from the (a), (b-1), and (b-2) were observed at the same positions as in the copolymer A-1, and the total of the integrated values was 6.14.

Furthermore, the resonance lines assigned to 1,2-substituted ethylene groups of (ta1), (ta2), and (tb1) were also observed at the same positions as in the copolymer A-1, and as a result of analysis in the same manner as in Example 1, the integrated value was determined to be 0.25.

From the ratio of the above integrated values, the proportion of the unsaturated bond functional groups derived from vinyl groups contained in (a1) and (ta1) to the number of unsaturated bond functional groups was calculated to be 79.8 mol %, and the proportion of the unsaturated bond functional groups derived from 1,2-substituted ethylene groups contained in (ta1), (ta2), and (tb1) was calculated to be 20.2 mol %. From (Expression 2), the functional group equivalent of the 1,2-substituted ethylene groups was calculated to be 781 (g/eq.).

The copolymer C-2 was soluble in toluene, xylene, tetrahydrofuran, dichloroethane, or chloroform, and no observable gel was generated.

The resulting analysis of each element of chlorine, bromine, and iodine demonstrated that each content was below the lower detection limit (5 ppm).

### Comparative Example 6

A copolymer D was synthesized according to Example 2 described in JP4338951B. Namely, a 1.0 L flask was charged with 0.29 mol (42.6 ml) of divinylbenzene, 0.012 mol (1.73 ml) of ethylvinylbenzene, 11.0 ml of a dichloroethane solution (concentration: 0.063 mmol/ml) of 1-chloroethylbenzene (0.70 mmol), dichloroethane (600 ml) and toluene (dielectric constant: 2.35) 100 ml, and added with 14.6 ml of a dichloroethane solution (concentration: 0.068 mmol/ml) of 1.00 mmol of SnCl₄ at 70 °C, and the mixture was reacted for 30 minutes. The polymerization reaction was quenched with a small amount of methanol bubbled with nitrogen, and then the reaction mixture solution was poured into a large amount of methanol at room temperature to recover the resulting white precipitate. The recovered white precipitate was washed with methanol, filtered, dried, and weighed to yield 48.3 g of the copolymer D.

The copolymer D obtained was analyzed by GPC, resulting in a copolymer D having an Mn of 1,850, an Mw of 4,650, and an Mw/Mn of 2.51. The vinyl equivalent of the copolymer D was measured to be 132 (g/eq.), and the number of unsaturated bond functional groups was calculated to be 14.02 from (Expression 1).

From the results of GC analysis, each structure included in the copolymer was calculated as follows.
The structural unit derived from divinylbenzene (a): 98.0 mol % (98.0 wt %)
The structural unit derived from ethylvinylbenzene (b-1): 2.00 mol % (2.03 wt %)

Also, a 1H-NMR analysis was carried out in the same manner as for the copolymer A-1, and the obtained resonance lines were observed in the same range as for the copolymer C-1.

The resonance lines assigned to aromatic rings in the structural units derived from the (a) and (b-1) were observed at the same positions as in the copolymer C-1, and the total of the integrated values was 4.14.

Furthermore, the resonance lines assigned to 1,2-substituted ethylene groups of (ta1), (ta2), and (tb1) were also observed at the same positions as in the copolymer C-1, and as a result of analysis in the same manner as in Example 1, the integrated value was determined to be 0.020.

From the ratio of the above integrated values, the proportion of the unsaturated bond functional groups derived from vinyl groups contained in (a1) and (ta1) to the number of unsaturated bond functional groups was calculated to be 98.0 mol %, and the proportion of the unsaturated bond functional groups derived from 1,2-substituted ethylene groups contained in (ta1), (ta2), and (tb1) was calculated to be 2.00 mol %. From (Expression 2), the functional group equivalent of the 1,2-substituted ethylene groups was calculated to be 37,390 (g/eq.).

The copolymer D was soluble in toluene, xylene, tetrahydrofuran, dichloroethane, or chloroform, and no observable gel was generated.

The analysis of each element of chlorine, bromine, and iodine demonstrated that the content of bromine and iodine was below the lower detection limit (5 ppm), whereas the content of chlorine was 1% or more.

### Examples 2, 3 and Comparative Examples 1 to 6

Each copolymer composition varnish was obtained in the same manner as in Example 1, using the compounding compositions shown in Table 1. Using the obtained copolymer composition varnish, physical properties thereof were measured according to the procedures described in each of the test methods described above. The obtained results are shown in Table 1.

### Examples 4 to 7 and Comparative Examples 7 and 8

Each copolymer composition varnish was obtained in the same manner as in Example 1, using the compounding compositions shown in Table 1. With the proviso that in each test method, physical properties were measured with only two changes described below. That is, as the first change, the method for homogenizing the mixture was changed to stirring it with a mechanical stirrer, and the second change is that the drying temperature and time of the film were changed to 110 °C and 5 minutes in the above 6) Measurement of coefficient of linear thermal expansion (CTE) of cured product, and 7) Minimum melt viscosity (η1) and η2. The obtained results are shown in Table 2.

TABLE 1

| | | | | Compar- | Compar- | Compar- | Compar- | Compar- | Compar- |
|---|---|---|---|---|---|---|---|---|---|
| | | | | ative | ative | ative | ative | ative | ative |
| | Example | Example | Example | Example | Example | Example | Example | Example | Example |
| Item | 1 | 2 | 3 | 1 | 2 | 3 | 4 | 5 | 6 |
| Copolymer A-1 | 100 | 0 | 0 | 0 | 0 | 0 | 0 | 0 | 0 |
| Copolymer A-2 | 0 | 100 | | 0 | 0 | 0 | 0 | 0 | 0 |
| Copolymer A-3 | 0 | 0 | 100 | 0 | 0 | 0 | 0 | 0 | 0 |
| Copolymer B-1 | 0 | 0 | | 100 | 0 | 0 | 0 | 0 | 0 |
| Copolymer B-2 | 0 | 0 | 0 | 0 | 100 | 0 | 0 | 0 | 0 |
| Copolymer B-3 | 0 | 0 | 0 | 0 | 0 | 100 | 0 | 0 | 0 |
| Copolymer C-1 | 0 | 0 | 0 | 0 | 0 | 0 | 100 | 0 | 0 |
| Copolymer C-2 | 0 | 0 | 0 | 0 | 0 | 0 | 0 | 100 | 0 |
| Copolymer D | 0 | 0 | 0 | 0 | 0 | 0 | 0 | 0 | 100 |
| Solvent | 85 | 85 | 85 | 100 | 85 | 100 | 85 | 85 | 100 |
| Polymerization | 0.5 | 0.5 | 0.5 | 0.5 | 0.5 | 0.5 | 0.5 | 0.5 | 0.5 |
| initiator G | | | | | | | | | |
| Stabilizer H | 0.2 | 0.2 | 0.2 | 0.2 | 0.2 | 0.2 | 0.2 | 0.2 | 0.2 |
| Number- | 1200 | 930 | 1400 | 3020 | 1500 | 2080 | 1090 | 950 | 1850 |
| average | | | | | | | | | |
| molecular | | | | | | | | | |
| weight | | | | | | | | | |
| (Mn) [-] | | | | | | | | | |
| Weight- | 10500 | 9500 | 12500 | 40500 | 12500 | 30800 | 12300 | 13100 | 4650 |
| average | | | | | | | | | |
| molecular | | | | | | | | | |
| weight | | | | | | | | | |
| (Mw) [-] | | | | | | | | | |
| Molecular | 8.75 | 10.22 | 8.93 | 13.41 | 8.33 | 14.81 | 11.28 | 13.79 | 2.51 |
| weight | | | | | | | | | |
| distribution | | | | | | | | | |
| (Mw/Mn) | | | | | | | | | |
| Vinyl | 410 | 380 | 398 | 445 | 831 | 486 | 193 | 158 | 132 |
| equivalent | | | | | | | | | |
| [g/eq.] | | | | | | | | | |
| Number of | 2.93 | 2.45 | 3.52 | 6.79 | 1.81 | 4.28 | 5.65 | 6.01 | 14.02 |
| unsaturated | | | | | | | | | |
| bond | | | | | | | | | |
| functional | | | | | | | | | |
| groups | | | | | | | | | |
| Functional | 3827 | 2615 | 4820 | 5779 | 3660 | 5141 | 783 | 781 | 37390 |
| group 1 | | | | | | | | | |
| equivalent of, | | | | | | | | | |
| 2-substituted | | | | | | | | | |
| ethylene | | | | | | | | | |
| group | | | | | | | | | |
| CTE [ppm] | 145 | 178 | 140 | 136 | 303 | 198 | 138 | 135 | 96 |
| η2/η1 | 3.18 | 1.86 | 4.54 | 26.80 | 2.45 | 13.20 | 20.85 | 7.40 | >100 |
| η1 [Pa · s] | 29.09 | 12.35 | 36.02 | 114.7 | 36.52 | 70.52 | 26.78 | 24.90 | 64.32 |
| η2 [Pa · s] | 92.42 | 22.95 | 163.5 | 3073 | 89.57 | 930.9 | 558 | 184 | >10000 |
| Resin | 23% | 27% | 21% | 8% | 25% | 13% | 12% | 19% | <1% |
| flowability | | | | | | | | | |
| [%] | | | | | | | | | |
| Adhesive | ○ | ○ | ○ | ○ | ○ | ○ | x | x | x |
| strength | | | | | | | | | |
| before | | | | | | | | | |
| HAST test | | | | | | | | | |
| Adhesive | | ○ | ○ | ○ | ○ | ○ | x | x | x |
| strength after | | | | | | | | | |
| HAST test | | | | | | | | | |
| Solubility to | ○ | ○ | ○ | ○ | ○ | ○ | ○ | ○ | ○ |
| specific | | | | | | | | | |
| solvent | | | | | | | | | |
| Halogen | N.D. | N.D. | N.D. | N.D. | N.D. | N.D. | N.D. | N.D. | >10000 |
| content | | | | | | | | | |
| [ppm] | | | | | | | | | |
| Halogen | — | — | — | — | — | — | — | — | CI |
| species | | | | | | | | | |
| Dielectric | 0.0011 | 0.0012 | 0.0011 | 0.0012 | 0.0011 | 0.0011 | 0.0016 | 0.0013 | 0.0058 |
| loss tangent | | | | | | | | | |
| @18 GHz [-] | | | | | | | | | |

TABLE 2

| | | | | | Comparative | Comparative |
|---|---|---|---|---|---|---|
| Item | Example 4 | Example 5 | Example 6 | Example 7 | Example 7 | Example 8 |
| Copolymer A-1 | 85 | | | | | |
| Copolymer A-2 | 0 | | 90 | 80 | | |
| Copolymer A-3 | 0 | 95 | | | | |
| Copolymer B-2 | 0 | | | | 85 | |
| Copolymer C-2 | 0 | | | | | 90 |
| Thermosetting compound E-1 | 15 | | | 15 | 15 | 10 |
| Thermosetting compound E-2 | 0 | | 5 | | | |
| Thermoplastic resin F | 0 | 5 | 5 | 5 | | 5 |
| Solvent toluene | 57 | 100 | 100 | 120 | 57 | 70 |
| Polymerization initiator G | 0.5 | 0.5 | 0.5 | 0.5 | 0.5 | 0.5 |
| Stabilizer H | 0.2 | 0.2 | 0.2 | 0.2 | 0.2 | 0.2 |
| Inorganic filler I | | | | 20 | | |
| CTE [ppm] | 135 | 155 | 194 | 115 | 287 | 155 |
| η2/η1 | 4.55 | 3.09 | 3.21 | 4.08 | 3.79 | 5.33 |
| η1 [Pa · s] | 17.45 | 52.55 | 72.37 | 95.60 | 22.73 | 36.74 |
| η2 [Pa · s] | 79.33 | 162.14 | 232.3 | 389.8 | 86.2 | 195.8 |
| Resin flowability [%] | 25% | 19% | 18% | 16% | 27% | 19% |
| Adhesive strength before HAST test | ○ | ○ | ○ | ○ | ○ | ○ |
| Adhesive strength after HAST test | ○ | ○ | ○ | ○ | × | x |
| Loss tangent @18 GHz [-] | 0.0011 | 0.0012 | 0.0014 | 0.0010 | 0.0011 | 0.0013 |

### INDUSTRIAL APPLICABILITY

The soluble polyfunctional vinyl aromatic copolymers of the present invention can be processed into a formed material, a sheet or a film, and can be used as a low dielectric material, an insulating material, a heat-resistant material, a structural material, and the like, which can satisfy properties such as a low dielectric constant, low water absorption, and high heat resistance, in the fields of the electrical industry, aerospace industry, and the like. In particular, they can be applied to single-sided, double-sided, and multi-layer printed circuit boards, a flexible printed circuit board, a build-up board, and the like, a semiconductor-related material or an optical material, and further to paints, a photosensitive material, an adhesive, a sewage treatment agent, a heavy metal collector, an ion exchange resin, an antistatic agent, an antioxidant, an anti-fogging agent, a corrosion inhibitor, a resist-dyeing agent, a bactericide, an insect repellent, a medical material, an aggregating agent, a surfactant, a lubricant, a binder for solid fuels, a conductive treatment agent, and the like.

The curable composition of the present invention has high dielectric properties, yields a cured product with high adhesion reliability even in harsh environments, has excellent resin flowability, low thermal expansion, and excellent flatness of a wiring layer when embedded therewith. Therefore, in fields such as the electric/electronic industry and the aerospace industry, there can be provided a cured formed article that is free from a forming defect such as warpage, in response to the strong demand for miniaturized and thinner products in recent years, as a dielectric material, an insulating material, a heat-resistant material, a structural material, and the like. Furthermore, due to the excellent flatness of a wiring layer when embedded therewith as well as adhesiveness to different materials, a resin composition, a cured product, or a material containing the same, which is excellent in its reliability, can be achieved.

1. A soluble polyfunctional vinyl aromatic copolymer, which is a polyfunctional vinyl aromatic copolymer comprising a structural unit derived from a divinyl aromatic compound (a) and a structural unit derived from a monovinyl aromatic compound (b),
wherein the structural unit derived from a divinyl aromatic compound (a) has a vinyl group-containing unit represented by the following formula (a1), a 1,2-substituted ethylene group-containing unit represented by the following formula (ta2), a cross-linked structural unit represented by the following formula (a2), and a structural unit represented by the following formula (ta1) containing both a vinyl group and a 1,2-substituted ethylene group; and the structural unit derived from a monovinyl aromatic compound (b) has a structural unit represented by the following formula (b1) and a 1,2-substituted ethylene group-containing terminal unit represented by the following formula (tb1), and
wherein the polyfunctional vinyl aromatic copolymer has a total number of unsaturated bond functional groups (excluding an unsaturated bond group in an aromatic ring) in one molecule of 2.1 or more and less than 4.0, a functional group equivalent of 1,2-substituted ethylene groups derived from the following formulae (ta1), (ta2), and (tb1) of 1,000 or more, a number-average molecular weight of 300 to 10,000, and a molecular weight distribution (Mw/Mn) represented by a ratio of a weight-average molecular weight to a number-average molecular weight of 50 or less, and is soluble in toluene, xylene, tetrahydrofuran, dichloroethane, or chloroform, and does not comprise a halogen element other than fluorine as an impurity in an amount of 5 ppm or more: 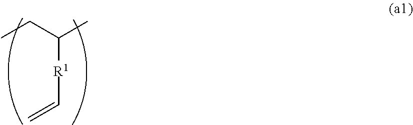
wherein R1 represents an aromatic hydrocarbon group having 6 to 30 carbon atoms; 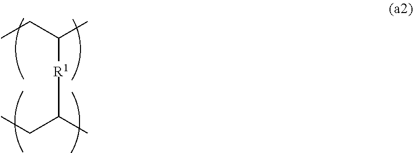
wherein R1 is as defined for formula (a1); 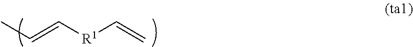
wherein R1 is as defined for formula (a1); 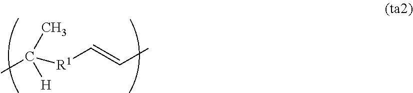
wherein R1 is as defined for formula (a1); 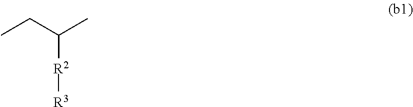
wherein R2 represents an aromatic hydrocarbon group having 6 to 30 carbon atoms, and R3 represents hydrogen or a hydrocarbon group having 1 to 12 carbon atoms; and 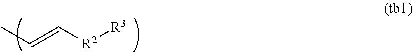
wherein R2 and R3 are as defined for formula (b1).

2. A method for producing the soluble polyfunctional vinyl aromatic copolymer according to claim 1, comprising reacting a divinyl aromatic compound (a) and a monovinyl aromatic compound (b) in the presence of a Lewis acid catalyst (d) free of a halogen other than fluorine and a Lewis base compound (e), wherein 18 mol % or more and less than 35 mol % of the divinyl aromatic compound (a) is used relative to a total of (a) and (b), and polymerization is performed at a temperature of 85 to 120 °C.

3. A curable composition comprising the soluble polyfunctional vinyl aromatic copolymer according to claim 1 and a radical polymerization initiator.

4. The curable composition according to claim 3, wherein the curable composition has a minimum melt viscosity (η1) of 100 Pa·s or less, and a ratio of a melt viscosity (η2) at a temperature 5 °C higher than a temperature at which η1 is achieved, to η1, is less than 5.0.

5. The curable composition according to claim 3, further comprising a thermosetting compound and/or a thermoplastic resin.

6. The curable composition according to claim 3, further comprising an inorganic filler.

7. A cured product obtained by curing the curable composition according to claim 3.

8. A film obtained by forming the curable composition according to claim 3 into a film shape.

9. A curable composite material, comprising the curable composition according to claim 3 and a base material, wherein the curable composite material comprises the base material in a proportion of 5 to 90% by weight.

10. A cured composite material obtained by curing the curable composite material according to claim 9.

11. A laminate having a layer of the cured composite material according to claim 9 and a metal foil layer.

12. Metal foil with a resin, having a film formed of the curable composition according to claim 3 on one side of the metal foil.

13. A varnish for circuit board materials, obtained by dissolving the curable composition according to claim 3 in an organic solvent.
